(19) United States
(12) Patent Application Publication
(10) Pub. No.: US 2022/0406977 A1
(43) Pub. Date: Dec. 22, 2022

(54) PRINTED CIRCUIT STRUCTURE

(71) Applicant: DARFON ELECTRONICS CORP., Taoyuan City (TW)

(72) Inventors: Hsin-Cheng HO, Taoyuan City (TW); Heng-Yi HUANG, Taoyuan City (TW); Yi-Tung LO, Taoyuan City (TW)

(21) Appl. No.: 17/538,616

(22) Filed: Nov. 30, 2021

(30) Foreign Application Priority Data
Jun. 22, 2021 (TW) 110122719

(51) Int. Cl. H01L 33/62; H05K 1/03; H05K 1/11; H05K 1/02

(52) U.S. Cl. CPC H01L 33/62; H05K 1/03; H05K 1/11; H05K 1/0296

(57) ABSTRACT

A printed circuit structure includes a printed conductive pattern and a printed conductive adhesive pattern. The printed conductive pattern includes a first wire and a second wire. One of a first main contact portion of the first wire and a first main contact portion of a first adhesive of the printed conductive adhesive pattern extends in a first direction, while another thereof extends in a second direction perpendicular to the first direction. With different lengths in the first direction, manufacturing errors between the first wire and the first adhesive in the first direction can be contained without affecting the connection in between. Similarly, a second main contact portion of the second wire and a second main contact portion of a second adhesive of the printed conductive adhesive pattern can also adopt the same design in the first direction to ensure the electric connection.

This application claims the benefit of Taiwan Patent Application Serial No. 110122719, filed Jun. 22, 2021, the subject matter of which is incorporated herein by reference.

### BACKGROUND OF THE INVENTION

### (1) Field of the Invention

The invention relates to a circuit structure, and more particularly to a printed circuit structure that utilizes a design integrating a printed conductive pattern and a printed conductive adhesive pattern to contain possible errors in printing.

### (2) Description of the Prior Art

Recently, the need for disposing LED components on a circuit board is increasing. For example, through disposing an LED component on a circuit board of a keyboard, the LED component can contribute its light while a corresponding key is depressed to energize the LED component.

In the art, the printed circuit board furnished with metallic loops is usually formed on an insulation substrate by etching processes. Thus, if an LED component is to be mounted onto a printed circuit board, electrode leads of the LED are generally connected to corresponding metallic wiring on the printed circuit board through reflow soldering. However, since the soldering process is usually carried out in a high temperature furnace, so the associated manufacturing cost is always high.

In order to resolve the high cost problem in using the high temperature furnace for processing the reflow soldering upon the LED component, a resort by improving conductive adhesives to connect the LED component and the metallic wiring is introduced. Referring to FIG. 1, a schematic view of a conventional printed circuit structure who includes conductive adhesives to connect the LED component. As shown in FIG. 1, a printed circuit structure PA100 includes a printed conductive pattern PA1 and conductive adhesives PA2, in which the printed conductive pattern PA1 further includes a first wire end PA11 and a second wire end PA12, and the conductive adhesives PA2 include a first adhesive PA21 and a second adhesive PA22.

The first adhesive PA21 is to connect the first wire end PA11, while the second adhesive PA22 is connected with the second wire end PA12. Thereupon, a first electrode PA201 and a second electrode PA202 of an LED component PA200 can be connected to the first adhesive PA21 and the second adhesive PA22, respectively, and so the printed conductive pattern PA1 can connect electrically with the LED component PA200 via the conductive adhesives PA2.

Referring to FIG. 2, a schematic view shows that the conventional conductive adhesives are deviated from the corresponding printed conductive pattern due to possible errors in printing and coating processes. As shown in FIG. 1, though the conductive adhesives PA2 can be applied to connect electrically the LED component PA200 to the printed conductive pattern PA1, and since the conductive adhesives PA2 are formed on the printed conductive pattern PA1 through screen printing, so practically the conductive adhesives PA2 would be easily deviated from positions for connecting the printed conductive pattern PA1 due to errors in printing and coating. Actually, even though the LED component PA200 can be accurately disposed to connect the conductive adhesives PA2, yet the printing errors at the conductive adhesives PA2 may still fail the electric connection between the conductive adhesives PA2 and the printed conductive pattern PA1.

### SUMMARY OF THE INVENTION

Though the conductive adhesives can be applied to connect electrically the LED component to the printed conductive pattern on the conventional printed circuit structure, yet practically the conductive adhesives may be still unable to be disposed right on and thus adhered as designed to the printed conductive pattern due to the screen printing process for forming the conductive adhesives on the printed conductive pattern. Accordingly, it is an object of the present invention to provide a printed circuit structure that includes modified structures to prevent the conductive adhesives from being falsely applied to the printed conductive pattern.

In this invention, a printed circuit structure, formed on a base plate and applied to electrically connect an LED component including a first electrode and a second electrode, includes a printed conductive pattern and a printed conductive adhesive pattern.

The printed conductive pattern includes a first wire and a second wire. The first wire includes a first main contact portion extending in a first direction and having a first length in the first direction. The second wire includes a second main contact portion extending in the first direction and having a second length in the first direction.

The printed conductive adhesive pattern includes a first adhesive and a second adhesive. The first adhesive includes a first main adhesive portion extending in a second direction perpendicular to the first direction and having a third length less than the first length in the first direction. The first main adhesive portion is connected with the first main contact portion. The second adhesive includes a second main adhesive portion extending in the second direction and having a fourth length less than the second length in the first direction. The second main adhesive portion is connected with the second main contact portion.

The first adhesive and the second adhesive are connected with the first electrode and the second electrode, respectively.

In one embodiment of the present invention, the first wire further includes a first connection portion extending in the second direction to connect the first main contact portion as a unique piece. Preferably, the first connection portion is connected with a middle portion or an end of the first main contact portion as a unique piece.

In one embodiment of the present invention, the first adhesive further includes a first adhesive connection portion extending in the first direction to connect the first main adhesive portion as a unique piece, and the first electrode of the LED component is connected with the first adhesive connection portion. Preferable, the first adhesive connection portion is connected with a middle portion or an end of the first main adhesive portion as a unique piece.

In one embodiment of the present invention, the first main contact portion has a fifth length in the second direction, and the first main adhesive portion has a sixth length greater than the fifth length in the second direction.

In one embodiment of the present invention, the first main contact portion has a metal edge, and the first main adhesive portion and the metal edge, both electrically connected with the first main contact portion, are arranged to cross each other.

In another aspect of the present invention, a printed circuit structure is disposed on a base plate to electrically connect an LED component including a first electrode and a second electrode. The printed circuit structure includes a printed conductive pattern and printed conductive adhesives.

The printed conductive pattern includes a first wire and a second wire. The first wire includes a first main contact portion extending in a first direction and having a first length in a second direction perpendicular to the first direction. The second wire includes a second main contact portion extending in the first direction and having a second length extending in the second direction.

The printed conductive adhesive pattern include a first adhesive and a second adhesive. The first adhesive includes a first main adhesive portion extending in the second direction and having a third length greater than the first length in the second direction, and the first main adhesive portion is connected with the first main contact portion. The second adhesive includes a second main adhesive portion extending in the second direction and having a fourth length greater than the second length in the second direction, and the second main adhesive portion is connected with the second main contact portion.

The first adhesive and the second adhesive are connected with the first electrode and the second electrode, respectively.

In one embodiment of the present invention, the first adhesive further includes a first adhesive connection portion extending in the first direction to connect the first main adhesive portion as a unique piece, and the first electrode of the LED component is connected with the first adhesive connection portion. Preferably, the first adhesive connection portion is connected with a middle portion or an end of the first main adhesive portion as a unique piece.

In one embodiment of the present invention, the first main contact portion has a metal edge, and the first main adhesive portion and the metal edge, both electrically connected with the first main contact portion, are arranged to cross each other.

In a further aspect of the present invention, a printed circuit structure is formed on a base plate to electrically connect an LED component including a plurality of first electrodes and a plurality of second electrodes. The printed circuit structure includes a printed conductive pattern and printed conductive adhesive pattern.

The printed conductive pattern includes a plurality of first wires and a plurality of second wires. Each of the plurality of first wires includes a first main contact portion extending in a first direction and having a first length in the first direction.

Each of the plurality of second wires includes a second main contact portion extending in the first direction and having a second length in the first direction.

The printed conductive adhesive pattern includes a plurality of first adhesives and a plurality of second adhesives. Each of the plurality of first adhesives includes a first main adhesive portion extending in a second direction perpendicular to the first direction and having a third length less than the first length in the first direction. The first main adhesive portion of the each of the plurality of first adhesives is connected with the corresponding first main contact portion of the each of the plurality of the first wires.

Each of the plurality of second adhesives includes a second main adhesive portion extending in the second direction and having a fourth length less than the second length in the first direction, and the second main adhesive portion of the each of the plurality of second adhesives is connected with the corresponding second main contact portion of the each of the plurality of second wires.

The plurality of first adhesives and the plurality of second adhesives are connected with the plurality of first electrodes and the plurality of second electrodes, respectively.

In one embodiment of the present invention, each of the plurality of first wires further includes a first connection portion extending in the second direction to connect the first main contact portion as a unique piece. Preferably, the first connection portion is connected with a middle portion of the first main contact portion as a unique piece.

In one embodiment of the present invention, at least one of the plurality of first adhesives further includes a first adhesive connection portion extending in the first direction to connect the corresponding first main adhesive portion as a unique piece, and at least one of the plurality of first electrodes of he LED component is connected with the first adhesive connection portion. Preferably, the first adhesive connection portion is connected with an end of the first main adhesive portion as a unique piece.

In one more aspect of the present invention, a printed circuit structure is disposed on a base plate to electrically connect an LED component including a plurality of first electrodes and a plurality of second electrodes. The printed circuit structure includes a printed conductive pattern and a printed conductive adhesive pattern.

The printed conductive pattern includes a plurality of first wires and a plurality of second wires. Each of the plurality of first wires includes a first main contact portion extending in a first direction and having a first length in the first direction. Each of the plurality of second wires includes a second main contact portion in a second direction perpendicular to the first direction, and all the second main contact portions of the plurality of second wires are integrated to form a local wire span.

The printed conductive adhesive pattern includes a plurality of first adhesives and a second adhesive. Each of the plurality of first adhesives includes a first main adhesive portion extending in the second direction and having a third length less than the first length in the first direction, and the first main adhesive portion of the each of the plurality of first adhesives is connected with the corresponding first main contact portion of the each of the plurality of first wires. The second adhesive is extended in the first direction to connect with the second main contact portion of the each of the plurality of second wires, and has a second length greater than the local wire span in the first direction.

The plurality of first adhesives are individually connected with the plurality of first electrodes, and the second adhesive is connected with the plurality of second electrodes.

In one embodiment of the present invention, each of the plurality of first wires further includes a first connection portion extending in the second direction to connect the first main contact as a unique piece. Preferably, the first connection portion is connected with a middle portion of the first main contact portion as a unique piece.

As stated, this invention introduces the design to assign different lengths to the first main contact portion and the corresponding first main adhesive portion in the first direction, and also different lengths to the second main contact portion and the corresponding second main adhesive portion in the first direction, thus the allowable tolerance range for the first main adhesive portion to undergo the printing process can be enlarged, so possible connection failure with the printed conductive pattern due to manufacturing errors at the printed conductive adhesive pattern can be effective avoided, and thus the manufacturing yield of the printed circuit structure can be substantially enhanced.

All these objects are achieved by the printed circuit structure described below.

### BRIEF DESCRIPTION OF THE DRAWINGS

The present invention will now be specified with reference to its preferred embodiment illustrated in the drawings, in which:

FIG. 1 is a schematic view of a conventional printed circuit structure who includes conductive adhesives to connect the LED component;

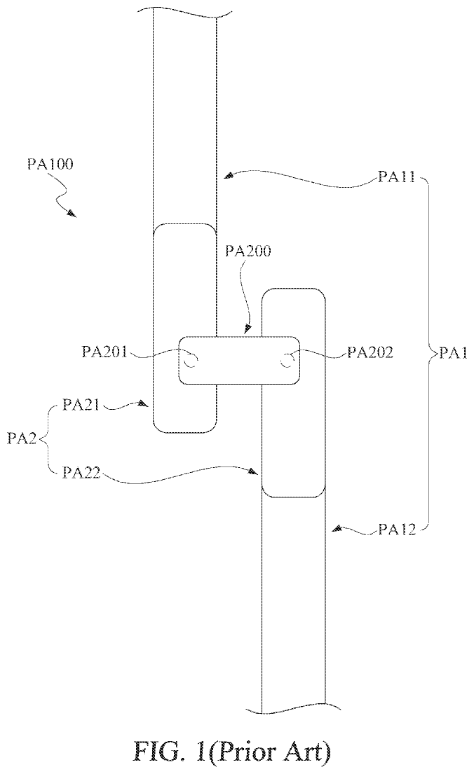

FIG. 2 is a schematic view showing that the conventional conductive adhesives are deviated from the corresponding printed conductive pattern due to possible errors in printing and coating processes;

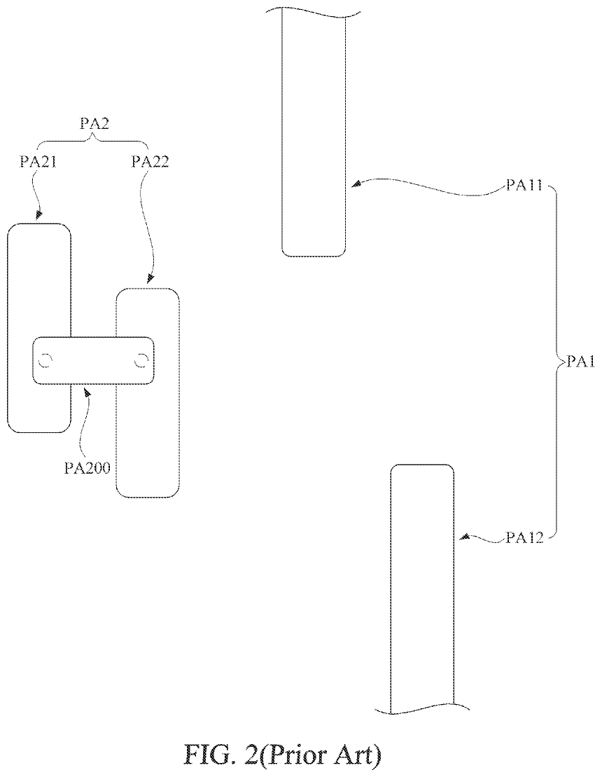

FIG. 3 is a schematic plane view of a first embodiment of the printed circuit structure in accordance with this disclosure;

FIG. 4 demonstrates schematically that an allowable printing range of the printed conductive adhesive pattern is enlarged by extending the first main contact portion and the second main contact portion in the first direction according to the first embodiment of the printed circuit structure of FIG. 3;

FIG. 5 is a schematic plane view of the first embodiment of the printed circuit structure of FIG. 3 applied to a keyboard module;

FIG. 6 is a schematic plane view of the first embodiment of the printed circuit structure of FIG. 3 applied to another keyboard module;

FIG. 7 is a schematic enlarged view of circle A of FIG. 6;

FIG. 8 is a schematic plane view of a second embodiment of the printed circuit structure in accordance with this disclosure;

FIG. 9 is a schematic plane view of a third embodiment of the printed circuit structure in accordance with this disclosure;

FIG. 10 is a schematic plane view of a fourth embodiment of the printed circuit structure in accordance with this disclosure;

FIG. 11 is a schematic view of a fifth embodiment of the printed circuit structure in accordance with this disclosure;

FIG. 12 is a schematic plane view of a sixth embodiment of the printed circuit structure in accordance with this disclosure;

FIG. 13 is a schematic plane view of a seventh embodiment of the printed circuit structure in accordance with this disclosure;

FIG. 14 is a schematic plane view of an eighth embodiment of the printed circuit structure in accordance with this disclosure; and

FIG. 15 is a schematic plane view of a ninth embodiment of the printed circuit structure in accordance with this disclosure.

### DESCRIPTION OF THE PREFERRED EMBODIMENT

The invention disclosed herein is directed to a printed circuit structure. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

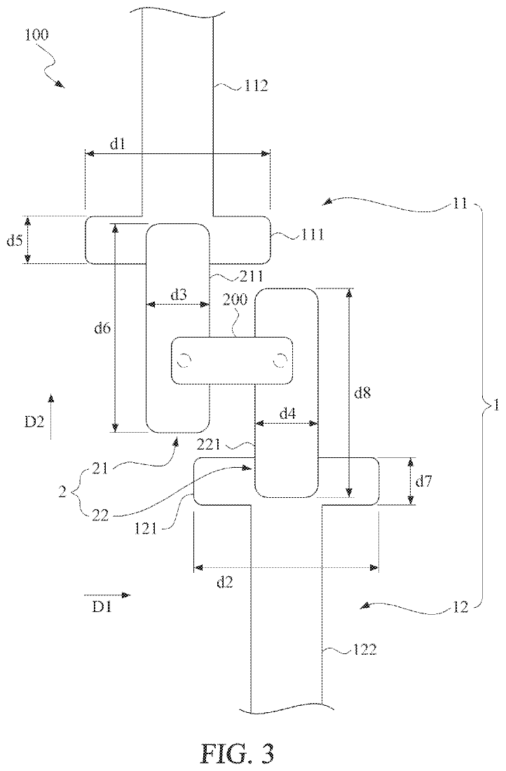

Referring to FIG. 3, a schematic plane view of a first embodiment of the printed circuit structure in accordance with this disclosure is illustrated. As shown in FIG. 3, a printed circuit structure 100 includes a printed conductive pattern 1 and a printed conductive adhesive pattern 2.

The printed conductive pattern 1 includes a first wire 11 and a second wire 12. The first wire 11 includes a first main contact portion 111 and a first connection portion 112, in which the first main contact portion 111 is extended in a first direction D1, and the first connection portion 112 is extended in a second direction D2 perpendicular to the first direction D1 as a unique piece to connect at a middle portion of the first main contact portion 111. In particular, the first main contact portion 11 has a first length d1 in the first direction D1 and a fifth length d5 in the second direction D2.

The second wire 12 includes a second main contact portion 121 and a second connection portion 122, in which the second main contact portion 121 is extended in the first direction D1, and the second connection portion 122 is extended in the second direction D2 by connecting as a unique piece to a middle portion of the second main contact portion 121. In particular, the second main contact portion 121 has a second length d2 in the first direction D1 and a seventh length d7 in the second direction D2.

The printed conductive adhesive pattern 2 includes a first adhesive 21 and a second adhesive 22. The first adhesive 21 includes a first main adhesive portion 211 extending in the second direction D2 to overlap in an adhesive manner at a middle portion of the first main contact portion 111. The first main adhesive portion 211 has a third length d3 in the first direction D1 less than the first length d1, and a sixth length d6 in the second direction D2 greater than the fifth length d5.

The second adhesive 22 includes a second main adhesive portion 221 extending in the second direction D2 to overlap in an adhesive manner at a middle portion of the second main contact portion 121. The second main adhesive portion 221 has a fourth length d4 in the first direction D1 less than the second length d2, and an eighth length d8 in the second direction D2 greater than the seventh length d7.

As described above, the first main adhesive portion 211 of the first adhesive 21 is configured to connect a first electrode (not labeled in the figure) of an LED component 200, while the second main adhesive portion 221 of the second adhesive 22 is configured to connect a second electrode (not labeled in the figure) of the same LED component 200. Thereupon, the circuit providing the first wire 11 and the second wire 12 can be electrically connected with the LED component 200.

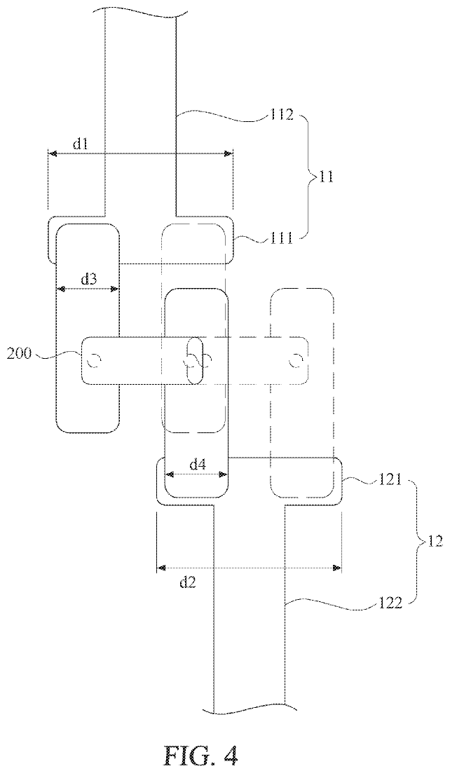

Referring now to FIG. 4, it is demonstrated schematically that an allowable printing range of the printed conductive adhesive pattern is enlarged by extending the first main contact portion and the second main contact portion in the first direction according to the first embodiment of the printed circuit structure of FIG. 3.

As shown in FIG. 3 and FIG. 4, since both the first main contact portion 111 and the second main contact portion 121 are extended in the first direction D1, and have the first length d1 greater than the third length d3 of the first main adhesive portion 211 and the second length d2 greater than the fourth length d4 of the second main adhesive portion 221, respectively. Thus, when the first main adhesive portion 211 and the second main adhesive portion 221 have the individual middle portions of the respective first main contact portion 111 and the respective second main contact portion 121 as corresponding targets for screen printing, then, even in the event that some unexpected manufacturing errors may have led to deviate from the middle portions of the first main contact portion 111 and the second main contact portion 121, the first main adhesive portion 211 and the second main adhesive portion 221 can be still formed individually on the first main contact portion 111 and the second main contact portion 121 within the scopes of the first length d1 and the third length d3, respectively. It implies that, with the first main contact portion 111 and the second main contact portion 121 to extend in the first direction D1, the allowable tolerance range for printing the printed conductive adhesive pattern 2 can be effectively enlarged, thus the possibility of the printed conductive adhesive pattern 2 failing to contact the printed conductive pattern 1 due to any type of deviation can be substantially reduced, and the associated manufacturing yield of the printed circuit structure 100 can be significantly enhanced.

Further, in the second direction D2, since the first main adhesive portion 211 and the second main adhesive portion 221 have the sixth length d6 greater than the fifth length d5 of the first main contact portion 111 and the eighth length d8 greater than the seventh length d7 of the second main contact portion 121, respectively, thus the first main adhesive portion 211 and the second main adhesive portion 221 can be effectively extended from the first main contact portion 111 and the second main contact portion 121, respectively, so as to provide an adhesive disposition of the LED component 200.

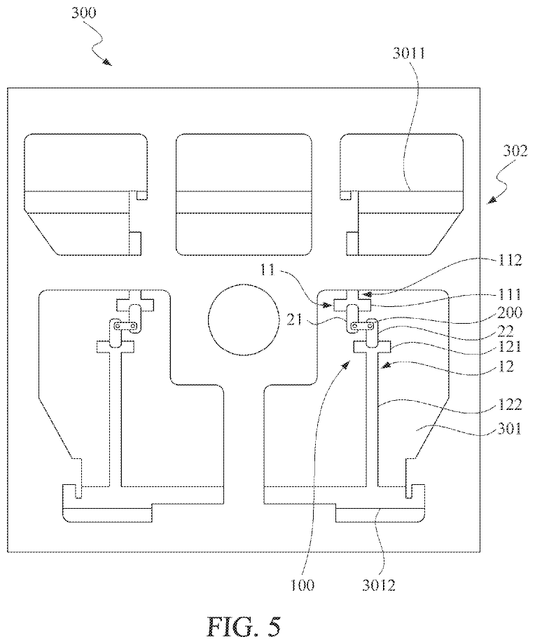

Referring now to FIG. 5, a schematic plane view of the first embodiment of the printed circuit structure of FIG. 3 applied to a keyboard module is shown. As illustrated in FIG. 3 and FIG. 5, the printed circuit structure 100 can be practically applied to a keyboard module 300 including a base plate 301, a keyboard frame 302 and a key (not shown in the figure). The keyboard frame 302 is disposed on the base plate 301, and the key is mounted to the keyboard frame 302. The base plate 301 can be a circuit board, and the first wire 1 of the printed circuit structure 100 can be part of the printed conductive pattern 1 formed on the circuit board by etching. The printed conductive adhesive pattern 2 is formed on the printed conductive pattern 1 of the base plate 301 by screen printing.

In addition, the base plate 301 further has thereon a first circuit 3011 and a second circuit 3012, in which the first circuit 3011 is energized through a depression at the key. The first connection portion 112 and the second connection portion 122 of the printed circuit structure 100 are electrically connected with the first circuit 3011 and the second circuit 3012, respectively. Thereupon, when the key is depressed, the first circuit 3011 can be energized to allow a current to flow through the LED component 200 via the printed circuit structure 100, and thus the LED component 200 can be lighted up.

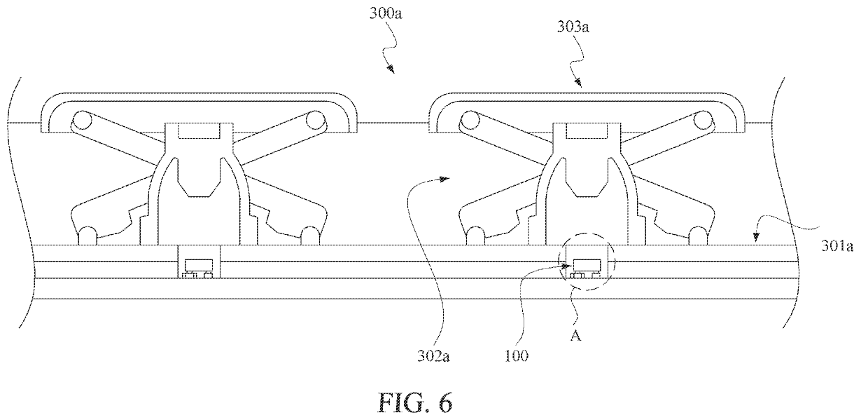

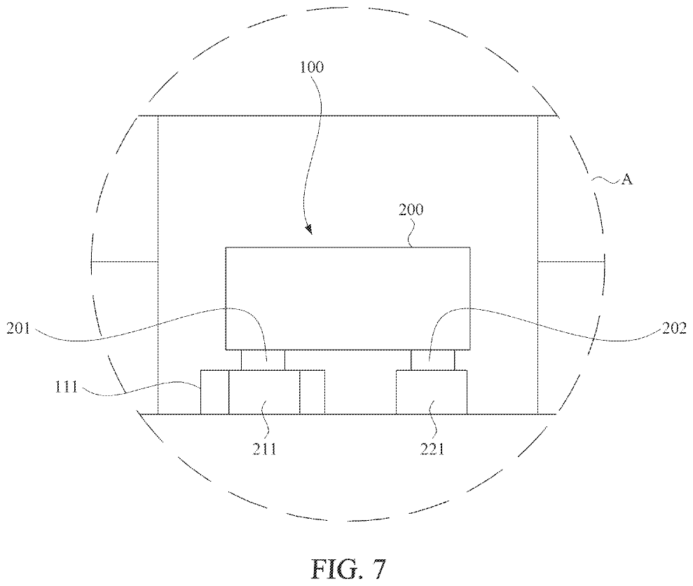

Refer now to FIG. 6 and FIG. 7; where FIG. 6 is a schematic plane view of the first embodiment of the printed circuit structure of FIG. 3 applied to another keyboard module, and FIG. 7 is a schematic enlarged view of circle A of FIG. 6.

As shown in FIG. 3, FIG. 6 and FIG. 7, the printed circuit structure 100 can be also applied to another keyboard module 300a including a base plate 301a, a key support mechanism 302a and a key 303a. Practically, the base plate 301a can be another circuit board. The key support mechanism 302a is disposed on the base plate 301a, and the key 303a is mounted to the key support mechanism 302a. In this application, the printed circuit structure 100 is disposed on the base plate 301a, and the first electrode 201 and the second electrode 202 of the LED component 200 are electrically connected with the first main adhesive portion 211 and the second main adhesive portion 221, respectively, as shown in FIG. 6 and FIG. 7.

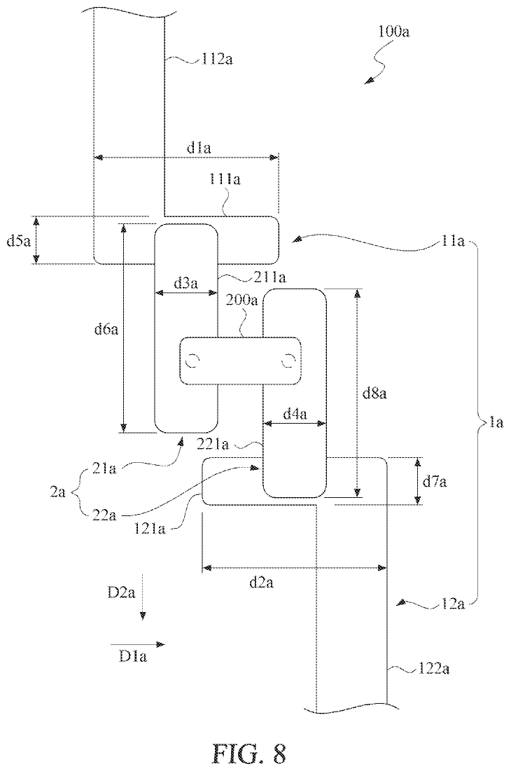

Referring to FIG. 8, a schematic plane view of a second embodiment of the printed circuit structure in accordance with this disclosure is provided. As shown, a printed circuit structure 100a includes a printed conductive pattern 1a and a printed conductive adhesive pattern 2a.

The printed conductive pattern 1a includes a first wire 11a and a second wire 12a. The first wire 11a includes a first main contact portion 111a and a first connection portion 112a, in which the first main contact portion 111a is extended in a first direction D1a, and the first connection portion 112a is extended in a second direction D2a perpendicular to the first direction D1a. The first connection portion 112a and the first main contact portion 111a are connected as a unique piece. In particular, the first main contact portion 111a has a first length d1a in the first direction D1a and a fifth length d5a in the second direction D2a.

The second wire 12a includes a second main contact portion 121a and a second connection portion 122a. The second main contact portion 121a is extended in the first direction D1a, and the second connection portion 122a is extended in the second direction D2a as a unique piece with the second main contact portion 121a. In particular, the second main contact portion 121a has a second length d2a in the first direction D1a and a seventh length d7a in the second direction D2a.

The printed conductive adhesive pattern 2a includes a first adhesive 21a and a second adhesive 22a. The first adhesive 21a includes a first main adhesive portion 211a to overlap a middle portion of the first main contact portion 111a in an adhesive manner, and has a third length d3a less than the first length d1a in the first direction D1a and a sixth length d6a greater than the fifth length d5a in the second direction D2a. The second adhesive 22a includes a second main adhesive portion 221a to overlap adhesive part of the second main contact portion 121a, and has a fourth length d4a less than the second length d2a in the first direction D1a and an eighth length d8a greater than the seventh length d7a in the second direction D2a.

As described above, the first main adhesive portion 211a is configured to electrically connect a first electrode (not labeled in the figure) of an LED component 200a, while the second main adhesive portion 221a is configured to electrically connect a second electrode (not labeled in the figure) of the same LED component 200a, such that the circuit having the first wire 11a and the second wire 12a can be used to energize the LED component 200a.

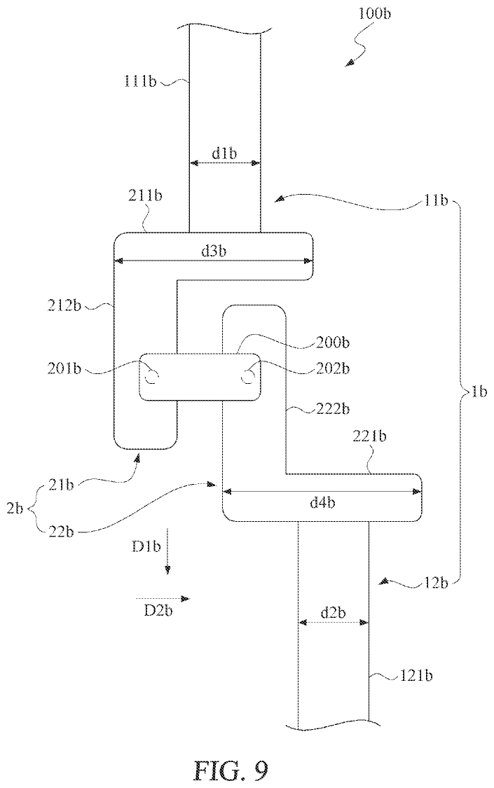

Referring to FIG. 9, a schematic plane view of a third embodiment of the printed circuit structure in accordance with this disclosure is illustrated. As shown in FIG. 9, a printed circuit structure 100b includes a printed conductive pattern 1b and a printed conductive adhesive pattern 2b.

The printed conductive pattern 1b includes a first wire 11b and a second wire 12b. The first wire 11b includes a first main contact portion 111b extending in a first direction D1b. The first main contact portion 111b has a first length d1b in a second direction D2b perpendicular to the first direction D1b.

The second wire 12b includes a second main contact portion 121b extending in the first direction D1b. The second main contact portion 121b has a second length d2b in the second direction D2b.

The printed conductive adhesive pattern 2b includes a first adhesive 21b and a second adhesive 22b. The first adhesive 21b includes a first main adhesive portion 211b and a first adhesive connection portion 212b. The first main adhesive portion 211b extending in the second direction D2b has a third length d3b greater than the first length d1b in the second direction D2b. The first main adhesive portion 211b has a middle portion thereof to overlap an end of the first main contact portion 111b through an adhesive means. The first adhesive connection portion 212b extending in the first direction D1b is formed as a unique piece with the first main adhesive portion 211b.

The second adhesive 22b includes a second main adhesive portion 221b and a second adhesive connection portion 222b. The second main adhesive portion 221b extending in the second direction D2b has a fourth length d4b greater than the second length d2b in the second direction D2b, and a middle portion of the second main adhesive portion 221b is adhered to an end of the second main contact portion 121b by overlapping. The second adhesive connection portion 222b extending in the first direction D1b is connected with an end of the second main adhesive portion 221b as a unique piece.

As described above, the first adhesive connection portion 212b is configured to connect a first electrode 201b of an LED component 200b, while the second adhesive connection portion 222b is configured to connect a second electrode 202b of the same LED component 200b. Thereupon, the circuit having the first wire 11b and the second wire 12b can be used to energize the LED component 200b.

In addition, since the printed circuit structure 100b of this embodiment provides the first main adhesive portion 211b having the third length d3b greater than the first length d1b in the second direction D2b and the second main adhesive portion 221b having the fourth length d4b greater than the second length d2b in the second direction D2b, thus, when the printed conductive adhesive pattern 2b are formed by a coating process, more rooms for containing possible errors in the second direction D2b can be provided to effectively avoid any connection failure between the printed conductive adhesive pattern 2b and the corresponding printed conductive pattern 1b, and so the manufacturing yield of the printed circuit structure 100b can be substantially enhanced.

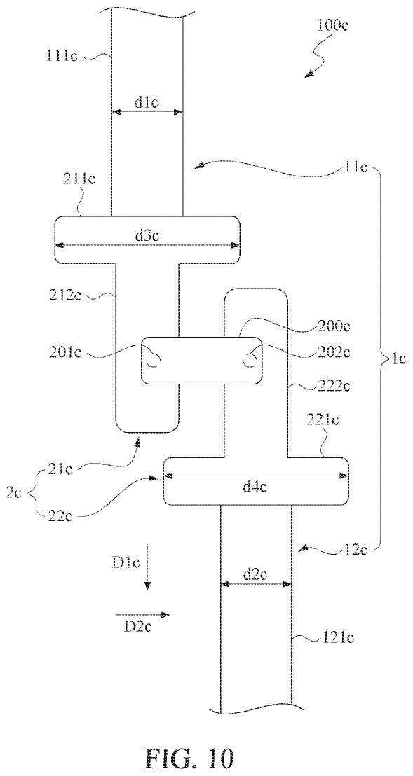

Referring to FIG. 10, a schematic plane view of a fourth embodiment of the printed circuit structure in accordance with this disclosure is illustrated. As shown in FIG. 10, a printed circuit structure 100c includes a printed conductive pattern 1c and a printed conductive adhesive pattern 2c.

The printed conductive pattern 1c includes a first wire 11c and a second wire 12c. The first wire 11c includes a first main contact portion 111c extending in a first direction D1c. The first main contact portion 111c has a first length d1c in a second direction D2c perpendicular to the first direction D1c.

The second wire 12c includes a second main contact portion 121c extending in the first direction D1c and having a second length d2c in the second direction D2c.

The printed conductive adhesive pattern 2c includes a first adhesive 21c and a second adhesive 22c. The first adhesive 21c includes a first main adhesive portion 211c and a first adhesive connection portion 212c. The first main adhesive portion 211c extending in the second direction D2c has a third length d3c greater than the first length d1c in the second direction D2c. The first main adhesive portion 211c has a middle portion thereof to overlap an end of the first main contact portion 111c by adhering. The first adhesive connection portion 212c is extended in the first direction D1c to connect the middle portion of the first main adhesive portion 211c as a unique piece.

The second adhesive 22c includes a second main adhesive portion 221c and a second adhesive connection portion 222c. The second main adhesive portion 221c extending in the second direction D2c has a fourth length d4c greater than the second length d2c in the second direction D2c, and has its own middle portion to connect the end of the second main contact portion 121c by overlapping. The second adhesive connection portion 222c extending in the first direction D1c is connected with the middle portion of the second main adhesive portion 221c as a unique piece.

As described above, the first adhesive connection portion 212c is configured to connect a first electrode 201c of an LED component 200c, while the second adhesive connection portion 222c is configured to connect a second electrode 202c of the same LED component 200b. Thereupon, the circuit having the first wire 11c and the second wire 12c can be used to energize the LED component 200c.

In addition, since the printed circuit structure 100c of this embodiment provides the first main adhesive portion 211c having the third length d3c greater than the first length d1c in the second direction D2c and the second main adhesive portion 221c having the fourth length d4c greater than the second length d2c in the second direction D2c, thus, when the printed conductive adhesive pattern 2c are formed by a coating process, more rooms for containing possible errors in the second direction D2c can be provided to effectively avoid any connection failure between the printed conductive adhesive pattern 2c and the corresponding printed conductive pattern 1c, and so the manufacturing yield of the printed circuit structure 100c can be substantially enhanced.

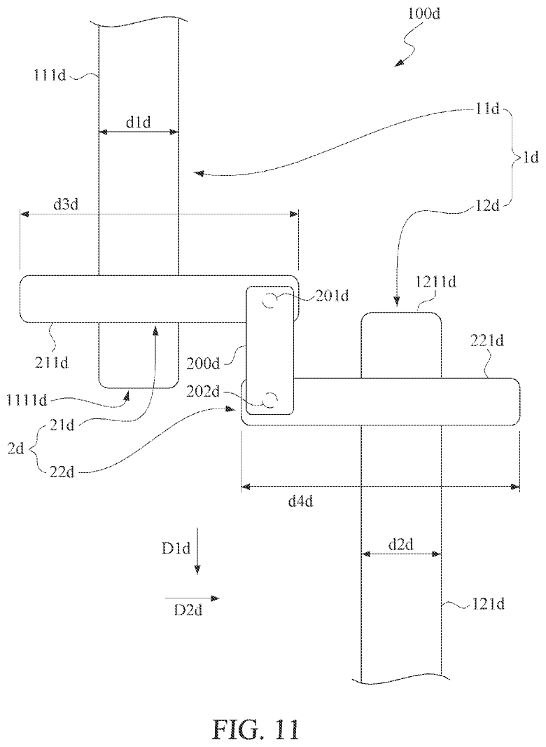

Referring to FIG. 11, a schematic view of a fifth embodiment of the printed circuit structure in accordance with this disclosure is illustrated. As shown in FIG. 11, a printed circuit structure 100d includes a printed conductive pattern 1d and a printed conductive adhesive pattern 2d.

The printed conductive pattern 1d includes a first wire 11d and a second wire 12d. The first wire 11d includes a first main contact portion 111d extending in a first direction D1d and having a first length did in a second direction D2d perpendicular to the first direction D1d. In addition, the first main contact portion 111d further has a metal edge 1111d.

The second wire 12d includes a second main contact portion 121d extending in the first direction D1d and having a second length d2d in the second direction D2d. In addition, the second main contact portion 121d further has a metal edge 1211d.

The printed conductive adhesive pattern 2d includes a first adhesive 21d and a second adhesive 22d. The first adhesive 21d includes a first main adhesive portion 211d extending in the second direction D2d and having a third length d3d greater than the first length did in the second direction D2d. In addition, the first main adhesive portion 211d and the metal edge 1111d, both electrically connected with the first main contact portion 111d, are arranged to cross each other.

The second adhesive 22d includes a second main adhesive portion 221d extending in the second direction D2d and having a fourth length d4d greater than the second length d2d in the second direction D2d. In addition, the second main adhesive portion 221d and the metal edge 1211d, both electrically connected with the second main contact portion 121d, are arranged to cross each other.

As described above, the first main adhesive portion 211d is configured to connect a first electrode 201d of an LED component 200d, while the second main adhesive portion 221d is configured to connect a second electrode 202d of the LED component 200d. Thereupon, the circuit having the first wire 11d and the second wire 12d can be used to energize the LED component 200d.

In this embodiment, by having the first main adhesive portion 211d to have the third length d3d greater than the first length did in the second direction D2d and the second main adhesive portion 221d to have the fourth length d4d greater than the second length d2d in the second direction D2d, then the printed conductive adhesive pattern 2d of the printed circuit structure 100d can be furnished with sufficient space in the second direction D2d for containing any possible manufacturing error while in the printing and coating process. Thereupon, connection failure between the printed conductive adhesive pattern 2d and the printed conductive pattern 1d due to manufacturing errors or tolerances can be significantly reduced, and the manufacturing yield of the printed circuit structure 100d can be substantially enhanced.

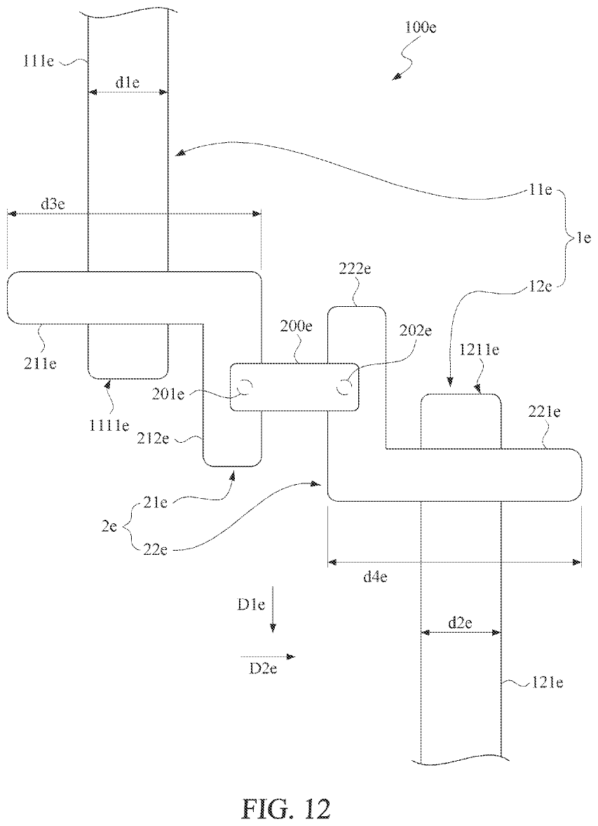

Referring to FIG. 12, a schematic plane view of a sixth embodiment of the printed circuit structure in accordance with this disclosure is illustrated. As shown in FIG. 12, a printed circuit structure 100e includes a printed conductive pattern 1e and a printed conductive adhesive pattern 2e.

The printed conductive pattern 1e includes a first wire 11e and a second wire 12e. The first wire 11e includes a first main contact portion 111e extending in a first direction D1e and having a first length die in a second direction D2e. In addition, the first main contact portion 111e further has a metal edge 111e.

The second wire 12e includes a second main contact portion 121e extending in the first direction D1e and having a second length d2e in the second direction D2e. In addition, the second main contact portion 121e further has a metal edge 1211e.

The printed conductive adhesive pattern 2e includes a first adhesive 21e and a second adhesive 22e. The first adhesive 21e includes a first main adhesive portion 211e and a first adhesive connection portion 212e. The first main adhesive portion 211e is extended in the second direction D2e, and has a third length d3e greater than the first length die in the second direction D2e. In addition, the first main adhesive portion 221e and the metal edge 1111e, both electrically connected with the first main contact portion 111e, are arranged to cross each other. The first adhesive connection portion 212e is extended in the first direction D1e, to connect with an end of the first main adhesive portion 211e as a unique piece.

The second adhesive 22e includes a second main adhesive portion 221e and a second adhesive connection portion 222e. The second main adhesive portion 221e is extended in the second direction D2e, and has a fourth length d4e greater than the second length d2e in the second direction D2e. In addition, the second main adhesive portion 221e and the metal edge 1211e, both electrically connected with the second main contact portion 121e, are arranged to cross each other. The second adhesive connection portion 222e is extended in the first direction D1e, to connect with an end of the second main adhesive portion 221e as a unique piece.

As described above, the first adhesive connection portion 212e is configured to connect a first electrode 201e of an LED component 200e, while the second adhesive connection portion 222e is configured to connect a second electrode 202e of the same LED component 200e. Thereupon, the circuit having the first wire 11e and the second wire 12e can be used to energize the LED component 200e.

In addition, the printed circuit structure 100e of this embodiment is similar to the aforesaid printed circuit structure 100e. In this embodiment, by having the third length d3e to be greater than the first length d1e and the fourth length d4e to be greater than the second length d2e, then the printed conductive adhesive pattern 2e of the printed circuit structure 100e can be furnished with sufficient space in the second direction D2e for containing any possible manufacturing error while in the printing and coating process. Thereupon, connection failure between the printed conductive adhesive pattern 2e and the printed conductive pattern 1e due to manufacturing errors or tolerances can be significantly reduced, and the manufacturing yield of the printed circuit structure 100e can be substantially enhanced.

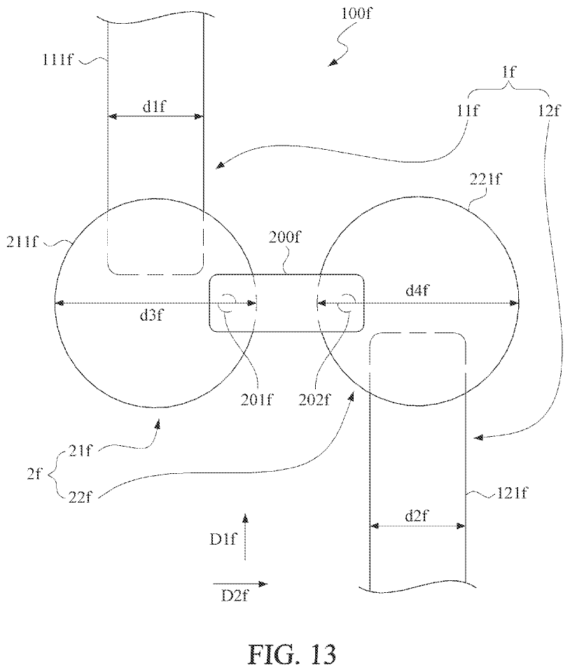

Referring to FIG. 13, a schematic plane view of a seventh embodiment of the printed circuit structure in accordance with this disclosure is illustrated. As shown in FIG. 13, a printed circuit structure 100f includes a printed conductive pattern if and a printed conductive adhesive pattern 2f.

The printed conductive pattern if includes a first wire 11f and a second wire 12f. The first wire 11f includes a first main contact portion 111f extending in a first direction D1f and having a first length d1f in a second direction D2f perpendicular to the first direction D1f.

The second wire 12f includes a second main contact portion 121f extending in the first direction D1f and having a second length d2f in the second direction D2f.

The printed conductive adhesive pattern 2f includes a first adhesive 21f and a second adhesive 22f. The first adhesive 21f includes a first main adhesive portion 211f having a third length d3f greater than the first length d1f in the second direction D2f. In addition, the first main adhesive portion 211f is adhered to the first main contact portion 111f.

The second adhesive 22f includes a second main adhesive portion 221f having a fourth length d4f greater than the second length d2f in the second direction D2f. In addition, the second main adhesive portion 221f is adhered to the second main contact portion 121f.

As described above, the first main adhesive portion 211f is configured to electrically connect a first electrode 201f of an LED component 200f, while the second main adhesive portion 221f is configured to electrically connect a second electrode 202f of the same LED component 200f. Thereupon, the circuit having the first wire 11f and the second wire 12f can be used to energize the LED component 200f.

In the printed circuit structure 100f of this embodiment, by having the third length d3f to be greater than the first length d1f and the fourth length d4f to be greater than the second length d2f, thus, while the printed conductive adhesive pattern 2f are formed by the printing and coating process, sufficient error-allowable space in the second direction D2f can be provided to effectively avoid possible connection failure between the printed conductive adhesive pattern 2f and the printed conductive pattern 1f, and also the manufacturing yield of the printed circuit structure 100f can be substantially enhanced.

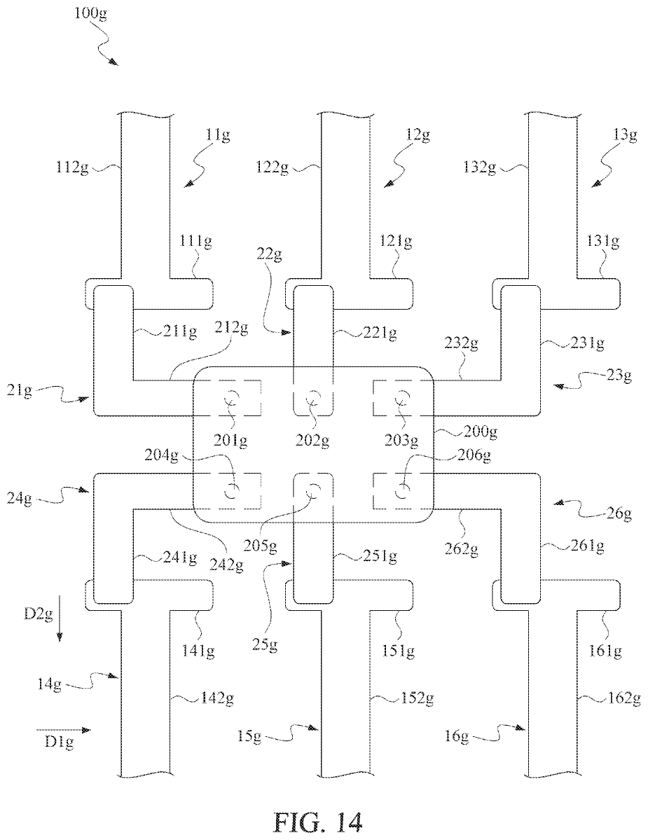

Referring to FIG. 14, a schematic plane view of a eighth embodiment of the printed circuit structure in accordance with this disclosure is illustrated. As shown in FIG. 14, a printed circuit structure 100g includes a printed conductive pattern 1g and a printed conductive adhesive pattern 2g.

The printed conductive pattern 1g includes three first wires 11g, 12g and 13g and three second wires 14g, 15g and 16g. The first wire 11g includes a first main contact portion 111g and a first connection portion 112g. The first main contact portion 111g is extended in a first direction D1g, and the first connection portion 112g is extended in a second direction D2g perpendicular to the first direction D1g to connect a middle portion of the first main contact portion 111g as a unique piece. The first main contact portion 111g has a first length (not labeled in the figure) in the first direction D1g and a fifth length (not labeled in the figure) in the second direction D2g.

The first wire 12g includes a first main contact portion 121g and a first connection portion 122g, and the first wire 13g includes a first main contact portion 131g and a first connection portion 132g. Since the first wires 12g and 13g are structured similarly to the first wire 11g, and thus details thereabout would be omitted herein.

The second wire 14g includes a second main contact portion 41g and a second connection portion 142g. The second main contact portion 141g is extended in the first direction D1g, and the second connection portion 142g is extended in the second direction D2g. The second main contact portion 141g has a second length (not labeled in the figure) in the first direction D1g and a seventh length (not labeled in the figure) in the second direction D2g.

The second wire 15g includes a second main contact portion 151g and a second connection portion 152g, and the second wire 16g includes a second main contact portion 161g and a second connection portion 162g. Since the second wires 15g and 16g are structured similarly to the second wire 14g, and thus details thereabout would be omitted herein.

The printed conductive adhesive pattern 2g includes three first adhesives 21g, 22g and 23g and three second adhesives 24g, 25g and 26g. The first adhesive 21g includes a first main adhesive portion 211g and a first adhesive connection portion 212g. The first main adhesive portion 211g is extended in the second direction D2g to connect an end of the first main contact portion 111g by overlapping, and has a third length (not labeled in the figure) less than the first length in the first direction D1g. The first adhesive connection portion 212g is extended in the first direction D1g to connect an end of the first main adhesive portion 211g as a unique piece.

The first adhesive 22g includes a first main adhesive portion 221g extending in the second direction D2g to connect an end of the first main contact portion 121g by overlapping and having a third length (not labeled in the figure) less than the first length of the first main contact portion 121g in the first direction D1g.

The first adhesive 23g includes a first main adhesive portion 231g and a first adhesive connection portion 232g. The first main adhesive portion 231g is extending in the second direction D2g to connect an end of the first main contact portion 131g by overlapping, and has a third length (not labeled in the figure) less than the first length of the first main contact portion 131g in the first direction D1g. The first adhesive connection portion 232g is extended in the first direction D1g to connect an end of the first main adhesive portion 231g as a unique piece. In this embodiment, the first adhesive 21g and the first adhesive 23g are symmetrically structured, with the first main adhesive portion 211g and the first main adhesive portion 231g to be parallel to each other, and the first adhesive connection portion 212g and the first adhesive connection portion 232g to extend toward each other, respectively. As shown in FIG. 14, the first adhesive connection portion 212g and the first adhesive connection portion 232g are extended to approach opposite sides of the first main adhesive portion 221g.

The second adhesive 24g includes a second main adhesive portion 241g and a second adhesive connection portion 242g. The second main adhesive portion 241g is extended in the second direction D2g to connect the second main contact portion 141g, and has a fourth length (not labeled in the figure) less than the second length in the first direction D1g.

The second adhesive 25g includes a second main adhesive portion 251g, and the second adhesive 26g includes a second main adhesive portion 261g and a second adhesive connection portion 262g. Since the second adhesives 24g, 25g and 26g of FIG. 14 are symmetric but up-side-down structures with respect to the first adhesives 21g, 22g and 23g, thus details about the second adhesives 24g, 25g and 26g would be omitted herein.

As described above, in this embodiment, similar to the first adhesives 21g and 23g extending to approach opposite sides of the first main adhesive portion 221g via the first adhesive connection portion 212g and the first adhesive connection portion 232g, respectively, the second adhesives 24g and 26g can be extended to approach opposite sides of the second main adhesive portion 251g via the second adhesive connection portion 242g and the second adhesive connection portion 262g, respectively. Thus, the first adhesive connection portion 212g, the first main adhesive portion 221g and the first adhesive connection portion 232g can be individually connected with three corresponding first electrodes 201g, 202g and 203g of an LED component 200g, and similarly, the second adhesive connection portion 242g, the second main adhesive portion 251g and the second adhesive connection portion 262g can be individually connected with another three corresponding second electrodes 204g, 205g and 206g of the same LED component 200g. Thereupon, with the first adhesives 21g, 22g and 23g respectively to electrically connect the first wires 11g, 12g and 13g, and the second adhesives 24g, 25g and 26g respectively to electrically connect the second wires 14g, 15g and 16g, the LED component 200g can be thus energized.

In addition, since the first length of the first main contact portion 111g, 121g or 131g in the first direction D1g is greater than the third length of the corresponding first main adhesive portion 211g, 221g or 231g in the first direction D1g, and also the second length of the second main contact portion 141g, 151g or 161g in the first direction D1g is greater than the fourth length of the corresponding second main adhesive portion 241g, 251g or 261g in the first direction D1g, thus the entire printed conductive adhesive pattern 2g in the first direction D1g can be provided with a larger allowable tolerance range for undergoing the printing process. As such, possible connection failure due to manufacturing errors between the printed conductive adhesive pattern 2g and the printed conductive pattern 1g can be effective avoided, and thus the manufacturing yield of the printed circuit structure 100g can be substantially enhanced.

As shown in FIG. 3 and FIG. 14, the connection relationship among the first wire 11g, the second wire 14g, the first adhesive 21g and the second adhesive 24g in the printed circuit structure 100g is similar to that among the first wire 11, the second wire 12, the first adhesive 21 and the second adhesive 22 in the printed circuit structure 100. Namely, in other embodiments, the first adhesive 21 can further include a first adhesive connection portion equivalent to the first adhesive connection portion 212g, such that the first adhesive connection portion can be extended in the first direction D1 as a unique piece from a middle portion or an end of the first main adhesive portion 211. Similarly, the second adhesive 22 can further include a second adhesive connection portion equivalent to the second adhesive connection portion 242g, such that the second adhesive connection portion can be extended in the first direction D1 as a unique piece from a middle portion or an end of the second main adhesive portion 221. Under such an arrangement, the first electrode of the LED component 200 can be connected electrically with the first adhesive connection portion, and the second electrode thereof can be connected electrically with the second adhesive connection portion.

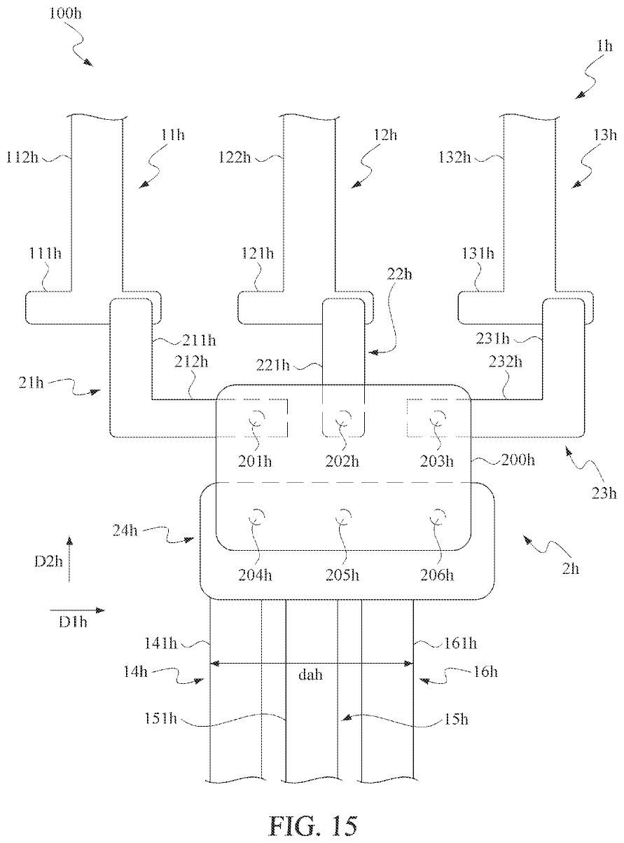

Referring to FIG. 15, a schematic plane view of a ninth embodiment of the printed circuit structure in accordance with this disclosure is illustrated. As shown in FIG. 15, a printed circuit structure 100h includes a printed conductive pattern 1h and a printed conductive adhesive pattern 2h.

The printed conductive pattern 1h includes three first wires 11h, 12h and 13h and three second wires 14h, 15h and 16h. The first wire 11h includes a first main contact portion 111h and a first connection portion 112h, the first wire 12h includes a first main contact portion 121h and a first connection portion 122h, and the first wire 13h includes a first main contact portion 131h and a first connection portion 132h. In this embodiment, the first wires 11h, 12h and 13h are structurally resembled to the first wires 11g, 12g and 13g of the previous embodiment, and thus details thereabout would be omitted herein.

The second wire 14h includes a second main contact portion 141h extending in a second direction D2h, the second wire 15h includes a second main contact portion 151h extending in the second direction D2h, and the second wire 16h includes a second main contact portion 161h also extending in the same second direction D2h. In particular, the second main contact portions 141h, 151b and 161h are integrated to form a local wire span dah in a first direction D1h perpendicular to the second direction D2h. As shown in FIG. 15, the local wire span dah is defined to be the distance between the two outmost metal edges of the second main contact portions 141h and 161h, respectively. In other words, the local wire span dah stands for the sum of all the widths and spacing in the first direction D1h of the second main contact portions 141h, 151h and 161h.

The printed conductive adhesive pattern 2h includes three first adhesives 21h, 22h and 23h and a second adhesive 24h.

The first adhesive 21h includes a first main adhesive portion 211h and a first adhesive connection portion 212h, the first adhesive 22h includes a first main adhesive portion 221h, and the first adhesive 23h includes a first main adhesive portion 231h and a first adhesive connection portion 232h. Since the first adhesives 21h, 22h and 23h are structurally resembled to the aforesaid first adhesives 21g, 22g and 23g, thus details thereabout would be omitted herein.

The second adhesive 24h is extending in the first direction D1h, and has a second length (not labeled in the figure) greater than the local wire span dah in the first direction D1h. Thereupon, the second adhesive 24h can contain spatially and thus connect all the second main contact portions 141h, 151h and 161h.

In this embodiment, the first adhesive connection portion 212h, the first main adhesive portion 221h and the first adhesive connection portion 232h can be connected with three first electrodes 201h, 202h and 203h of an LED component 200h, respectively, while the second adhesive 24h is configured to connect individually three second electrodes 204h, 205h and 206h of the same LED component 200h. Thereupon, the LED component 200h can be energized through the electric connection between the printed conductive adhesive pattern 2h and the printed conductive pattern 1h, in which the second adhesive 24h is connected individually with the second main contact portions 141h, 151b and 161h. Namely, with respect to the LED component 200h, the second adhesive 24h can be treated as leads of a common cathode or anode.

As described above, since the first length of the first main contact portion 1116, 121h or 131h is greater than the third length of the first main adhesive portion 211h, 221h or 231h in the first direction D1h, and also the second adhesive 24h contains spatially all the second main contact portions 141h, 151h and 161h in the first direction D1h, thus the entire printed conductive adhesive pattern 2h in the first direction D1h can be provided with a larger allowable tolerance range for undergoing the printing process. As such, possible connection failure due to manufacturing errors between the printed conductive adhesive pattern 2h and the printed conductive pattern 1b can be effective avoided, and thus the manufacturing yield of the printed circuit structure 100h can be substantially enhanced.

In summary, in comparison to the prior art that, when the conductive adhesives are utilized to electrically connect the LED component to the printed conductive pattern, the conductive adhesives may be deviated from the printed conductive pattern in the screen printing process, this invention introduces the design to assign different lengths to the first main contact portion and the corresponding first main adhesive portion in the first direction, and also different lengths to the second main contact portion and the corresponding second main adhesive portion in the first direction, thus the allowable tolerance range for the first main adhesive portion to undergo the printing process can be enlarged, so possible connection failure with the printed conductive pattern due to manufacturing errors at the printed conductive adhesive pattern can be effective avoided, and thus the manufacturing yield of the printed circuit structure can be substantially enhanced.

While the present invention has been particularly shown and described with reference to a preferred embodiment, it will be understood by those skilled in the art that various changes in form and detail may be without departing from the spirit and scope of the present invention.

What is claimed is:

1. A printed circuit structure, disposed on a base plate, applied to electrically connect an LED component, the LED component including a first electrode and a second electrode, the printed circuit structure comprising:
a printed conductive pattern, including:
a first wire, including a first main contact portion extending in a first direction and having a first length in the first direction; and
a second wire, including a second main contact portion extending in the first direction and having a second length in the first direction; and
a printed conductive adhesive pattern, including:
a first adhesive, including a first main adhesive portion extending in a second direction perpendicular to the first direction and having a third length less than the first length in the first direction, the first main adhesive portion being connected with the first main contact portion; and
a second adhesive, including a second main adhesive portion extending in the second direction and having a fourth length less than the second length in the first direction, the second main adhesive portion being connected with the second main contact portion;
wherein the first adhesive and the second adhesive are connected with the first electrode and the second electrode, respectively.

2. The printed circuit structure of claim 1, wherein the first wire further includes a first connection portion extending in the second direction to connect the first main contact portion as a unique piece.

3. The printed circuit structure of claim 2, wherein the first connection portion is connected with a middle portion or an end of the first main contact portion as a unique piece.

4. The printed circuit structure of claim 1, wherein the first adhesive further includes a first adhesive connection portion extending in the first direction to connect the first main adhesive portion as a unique piece, and the first electrode of the LED component is connected with the first adhesive connection portion.

5. The printed circuit structure of claim 4, wherein the first adhesive connection portion is connected with a middle portion or an end of the first main adhesive portion as a unique piece.

6. The printed circuit structure of claim 1, wherein the first main contact portion has a fifth length in the second direction, and the first main adhesive portion has a sixth length greater than the fifth length in the second direction.

7. The printed circuit structure of claim 1, wherein the first main contact portion has a metal edge, and the first main adhesive portion and the metal edge, both electrically connected with the first main contact portion, are arranged to cross each other.

8. A printed circuit structure, formed on a base plate, applied to electrically connect an LED component, the LED component including a first electrode and a second electrode, the printed circuit structure comprising:
a printed conductive pattern, including:
a first wire, including a first main contact portion extending in a first direction and having a first length in a second direction perpendicular to the first direction; and
a second wire, including a second main contact portion extending in the first direction and having a second length extending in the second direction; and
a printed conductive adhesive pattern, including:
a first adhesive, including a first main adhesive portion extending in the second direction and having a third length greater than the first length in the second direction, the first main adhesive portion being connected with the first main contact portion; and
a second adhesive, including a second main adhesive portion extending in the second direction and having a fourth length greater than the second length in the second direction, the second main adhesive portion being connected with the second main contact portion;
wherein the first adhesive and the second adhesive are connected with the first electrode and the second electrode, respectively.

9. The printed circuit structure of claim 8, wherein the first adhesive further includes a first adhesive connection portion extending in the first direction to connect the first main adhesive portion as a unique piece, and the first electrode of the LED component is connected with the first adhesive connection portion.

10. The printed circuit structure of claim 9, wherein the first adhesive connection portion is connected with a middle portion or an end of the first main adhesive portion as a unique piece.

11. The printed circuit structure of claim 8, wherein the first main contact portion has a metal edge, and the first main adhesive portion and the metal edge, both electrically connected with the first main contact portion, are arranged to cross each other.

12. A printed circuit structure, disposed on a base plate, applied to electrically connect an LED component, the LED component including a first electrode and a plurality of second electrodes, the printed circuit structure comprising:
a printed conductive pattern, including:
a plurality of first wires, each of the plurality of first wires including a first main contact portion extending in a first direction and having a first length in the first direction; and
a plurality of second wires, each of the plurality of second wires including a second main contact portion extending in the first direction and having a second length in the first direction; and
a printed conductive adhesive pattern, including:
a plurality of first adhesives, each of the plurality of first adhesives including a first main adhesive portion extending in a second direction perpendicular to the first direction and having a third length less than the first length in the first direction, the first main adhesive portion of the each of the plurality of first adhesives being connected with the corresponding first main contact portion of the each of the plurality of first wires; and
a plurality of second adhesives, each of the plurality of second adhesives including a second main adhesive portion extending in the second direction and having a fourth length less than the second length in the first direction, the second main adhesive portion of the each of the plurality of second adhesives being connected with the corresponding second main contact portion of the each of the plurality of second wires;
wherein the plurality of first adhesives and the plurality of second adhesives are connected with the plurality of first electrodes and the plurality of second electrodes, respectively.

13. The printed circuit structure of claim 12, wherein each of the plurality of first wires further includes a first connection portion extending in the second direction to connect the first main contact portion as a unique piece.

14. The printed circuit structure of claim 13, wherein the first connection portion is connected with a middle portion of the first main contact portion as a unique piece.

15. The printed circuit structure of claim 12, wherein at least one of the plurality of first adhesives further includes a first adhesive connection portion extending in the first direction to connect the corresponding first main adhesive portion as a unique piece, and at least one of the plurality of first electrodes of he LED component is connected with the first adhesive connection portion.

16. The printed circuit structure of claim 15, wherein the first adhesive connection portion is connected with an end of the first main adhesive portion as a unique piece.

17. A printed circuit structure, formed on a base plate, applied to electrically connect an LED component, the LED component including a plurality of first electrodes and a plurality of second electrodes, the printed circuit structure comprising:
a printed conductive pattern, including:
a plurality of first wires, each of the plurality of first wires including a first main contact portion extending in a first direction and having a first length in the first direction; and
a plurality of second wires, each of the plurality of second wires including a second main contact portion in a second direction perpendicular to the first direction, all the second main contact portions of the plurality of second wires being integrated to form a local wire span; and
a printed conductive adhesive pattern, including:
a plurality of first adhesives, each of the plurality of first adhesives including a first main adhesive portion extending in the second direction and having a third length less than the first length in the first direction, the first main adhesive portion of the each of the plurality of first adhesives being connected with the corresponding first main contact portion of the each of the plurality of first wires; and
a second adhesive, extended in the first direction to connect with the second main contact portion of the each of the plurality of second wires, having a second length greater than the local wire span in the first direction;
wherein the plurality of first adhesives are individually connected with the plurality of first electrodes, and the second adhesive is connected with the plurality of second electrodes.

18. The printed circuit structure of claim 17, wherein each of the plurality of first wires further includes a first connection portion extending in the second direction to connect the first main contact as a unique piece.

19. The printed circuit structure of claim 18, wherein the first connection portion is connected with a middle portion of the first main contact portion as a unique piece.
